(19) United States
(12) Patent Application Publication
(10) Pub. No.: US 2008/0066868 A1
(43) Pub. Date: Mar. 20, 2008

(54) FOCUS RING AND PLASMA PROCESSING APPARATUS

(75) Inventor: Noriiki MASUDA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/857,118

(22) Filed: Sep. 18, 2007

Related U.S. Application Data
(60) Provisional application No. 60/854,715, filed on Oct. 27, 2006.

(30) Foreign Application Priority Data
Sep. 19, 2006 (JP) 2006-253027

(51) Int. Cl. C23C 16/00

(52) U.S. Cl. 156/345.51

(57) ABSTRACT

A focus ring of a plasma processing apparatus for performing a plasma processing on a target substrate to be processed is disposed on the mounting table to surround the target substrate. The focus ring includes a first ring-shaped member made of a conductive material and having a stepped portion at an inner peripheral portion thereof, the stepped portion being positioned lower than a bottom surface of the target substrate mounted on the mounting table and extended below a peripheral portion of the target substrate. The focus ring further includes a second ring-shaped member made of an insulating material and disposed under the first ring-shaped member to be interposed between the first ring-shaped member and the mounting table.

### FIELD OF THE INVENTION

The present invention relates to a plasma processing apparatus for performing a plasma process, e.g., a plasma etching process, on a target substrate to be processed and a focus ring employed in the plasma processing apparatus.

### BACKGROUND OF THE INVENTION

Conventionally, a plasma processing apparatus such as a plasma etching apparatus and the like has been widely used in, e.g., a manufacturing process of fine electric circuits of a semiconductor device.

Well known as such plasma processing apparatus is a so-called parallel plate electrode type plasma processing apparatus, wherein target substrate, e.g., a semiconductor wafer, is mounted on a mounting table in a processing chamber, a plasma processing is carried out by generating a plasma by applying a high frequency power between the mounting table and an upper electrode facing the mounting table.

In such a plasma processing apparatus, there is known a method for improving an in-surface uniformity of the plasma processing by using an annular focus ring disposed on the mounting table to surround the target substrate. Moreover, also known is a technique for forming a focus ring with a ring-shaped conductive member and a ring-shaped insulating member disposed therebetween and generating an electric field oriented toward the ring-shaped conductive member from the target substrate, thereby preventing the plasma from reaching a backside surface of a peripheral portion of the target substrate, and also reducing the occurrence of deposition thereon (see, for example, Japanese Patent Laid-open Application No. 2005-277369).

The technique of forming the focus ring with the dual components of the ring-shaped conductive member and the ring-shaped insulating member disposed thereunder pertains to a plasma processing apparatus of a type which applies a high frequency power of a higher frequency to the upper electrode for plasma generation while applying a bias high frequency power having a lower frequency to the lower electrode (mounting table) for ion attraction. That is, in this conventional technique, the plasma generation is carried out by the high frequency power applied to the upper electrode, ion attraction state (incident angle of ions, arrival of ions at the backside surface of the target substrate, or the like) at the peripheral portion of the target substrate is controlled by adjusting the focus ring mounted on the lower electrode.

Meanwhile, in a conventional plasma processing apparatus of a type in which an upper electrode is electrically grounded and a plasma is generated by a high frequency power applied to a lower electrode (mounting table), the following problems have conventionally occurred.

That is, when a target substrate is etched in a plasma etching process, for example, an etching rate at a peripheral portion of the target substrate sometimes becomes higher or lower, depending on kinds of etching gases employed, even in case a same focus ring and a same plasma processing apparatus are used, which results in a deterioration of in-surface uniformity of the etching process. In particular, in case of an etching gas system which does not incur deposition (deposits), the in-surface uniformity may not be controlled by, e.g., adjusting a deposition amount. Therefore, it is required to improve the in-surface uniformity by controlling hardware.

### SUMMARY OF THE INVENTION

In view of the forgoing, the present invention provides a focus ring and a plasma processing apparatus capable of improving in-surface uniformity of plasma processing in comparison with the prior art.

In accordance with a first aspect of the present invention, there is provided a focus ring of a plasma processing apparatus for performing a plasma processing on a target substrate to be processed by applying a high frequency power to a mounting table mounting thereon the target substrate and generating a plasma in a space between the mounting table and an electrically grounded upper electrode disposed to face the mounting table, the focus ring being disposed on the mounting table to surround the target substrate and including: a first ring-shaped member made of a conductive material and having a stepped portion at an inner peripheral portion thereof, the stepped portion being positioned lower than a bottom surface of the target substrate mounted on the mounting table and extended below a peripheral portion of the target substrate; and a second ring-shaped member made of an insulating material and disposed under the first ring-shaped member to be interposed between the first ring-shaped member and the mounting table.

In this aspect, the second ring-shaped member may be made of alumina.

The first ring-shaped member may be made of silicon, carbon or SiC.

A top surface of a portion of the first ring-shaped member outside the stepped portion is formed as a flat portion positioned higher than a top surface of the target substrate mounted on the mounting table.

In accordance with a second aspect of the present invention, there is provided a plasma processing apparatus including: a processing chamber for performing a plasma process on a target substrate to be processed accommodated therein; a mounting table, disposed in the processing chamber, for mounting thereon the target substrate; a high frequency power supply for generating a plasma by supplying a high frequency power to the mounting table; an electrically grounded upper electrode disposed to face the mounting table and electrically grounded; a focus ring disposed on the mounting table to surround the target substrate, the focus ring including a first ring-shaped member made of a conductive material and having a stepped portion at an inner peripheral portion thereof, is the stepped portion being positioned lower than a bottom surface of the target substrate mounted on the mounting table and extended below a peripheral portion of the target substrate; and a second ring-shaped member made of an insulating material and disposed under the first ring-shaped member to be interposed between the first ring-shaped member and the mounting table.

In this aspect, the second ring-shaped member is made of alumina.

The first ring-shaped member is made of silicon, carbon or SiC.

A top surface of a portion of the first ring-shaped member outside the stepped portion is formed as a flat portion positioned higher than a top surface of the target substrate mounted on the mounting table.

In accordance with the present invention, there are provided a focus ring and a processing apparatus capable of improving an in-surface uniformity of plasma processing in comparison with the conventional art.

### BRIEF DESCRIPTION OF THE DRAWINGS

The above and other objects and features of the present invention will become apparent from the following description of embodiments given in conjunction with the accompanying drawings, in which:

FIG. 1 is a schematic configuration view of a plasma processing apparatus in accordance with an embodiment of the present invention;

FIG. 2 sets forth a schematic cross sectional configuration view of major parts of FIG. 1;

FIGS. 3A and 3B present diagrams to describe consumption of a focus ring in accordance with the present invention; and

FIGS. 4A and 4B provide diagrams to describe consumption of a conventional focus ring.

### DETAILED DESCRIPTION OF THE EMBODIMENTS

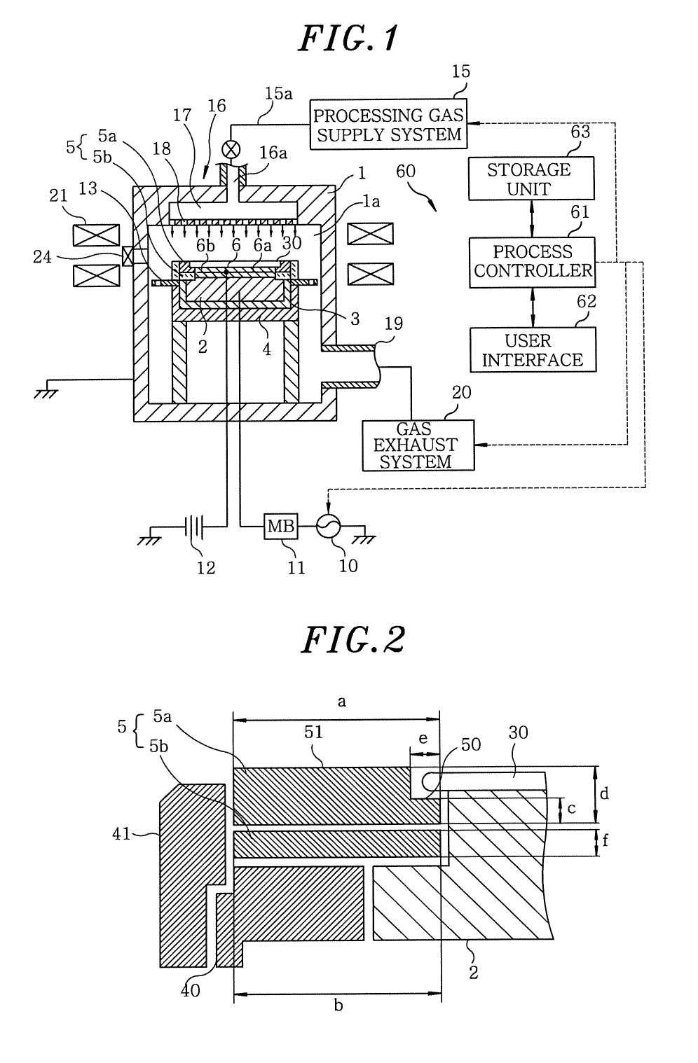

Hereinafter, embodiments of the present invention will be described with reference to the accompanying drawings that form a part hereof. FIG. 1 shows a schematic configuration of a plasma etching apparatus serving as a plasma processing apparatus in accordance with an embodiment of the present invention. The plasma etching apparatus includes a hermetically sealed processing chamber 1, which is electrically grounded. The processing chamber 1 has a cylindrical shape and is made of, e.g., aluminum. Disposed in the processing chamber 1 is a mounting table 2 for supporting thereon a target substrate to be processed, e.g., a semiconductor wafer 30 in a substantially horizontal manner. The mounting table 2 also functions as a lower electrode, and it is made of, e.g., a conductive material such as aluminum and is supported by a conductive support 4 via an insulating plate 3. Further, an annular focus ring 5 is disposed at the peripheral portion of the top surface of the mounting table 2 to surround the semiconductor wafer 30. The focus ring 5 includes a first ring-shaped member 5a made of a conductive material; and a second ring-shaped member 5b made of an insulating material, wherein the second ring-shaped member 5b is disposed under the first ring-shaped member 5a. A detailed configuration of the focus ring 5 will be explained later.

An RF power supply 10 is connected to the mounting table 2 via a matching box (MB) 11, and a high frequency power of a specific frequency (e.g., about 13.56 MHz) is applied from the RF power supply 10 to the mounting table 2. Meanwhile, a shower head 16 is parallely disposed above the mounting table 2. The shower head 16 is electrically grounded. Accordingly, the shower head 16 and the mounting table 2 are configured to function as a pair of facing electrodes (upper electrode and lower electrode).

An electrostatic chuck 6 for electrostatically attracting and holding the semiconductor wafer 30 thereon is provided on the top surface of the mounting table 2. The electrostatic chuck 6 has an electrode 6a embedded in an insulator 6b, and the electrode 6a is connected to a DC power supply 12. By applying a DC voltage to the electrode 6a from the DC power supply 12, the semiconductor wafer 30 is attracted and held on the electrostatic chuck 6 by, e.g., a Coulomb force.

A coolant path (not shown) is formed inside the mounting table 2. By circulating a coolant through the coolant path, the temperature of the semiconductor wafer 30 can be regulated at a desired temperature level. Further, a gas exhaust ring 13 is disposed outside the focus ring 5, and the gas exhaust ring 13 is connected with the processing chamber 1 via the support 4.

The shower head 16 disposed at the ceiling of the processing chamber 1 is provided with a plurality of gas injection openings 18 at its lower surface and includes a gas inlet 16a at the upper portion thereof. The shower head 16 has a hollow space 17 formed therein. One end of a gas supply line 15a is connected to the gas inlet 16a, and the other end of the gas supply line 15a is connected to a processing gas supply system 15 which serves to supply a processing gas (etching gas) for plasma etching.

The processing gas is introduced into the space 17 inside the shower head 16 from the processing gas supply system 15 via the gas supply line 15a and the gas inlet 16a so as to be discharged toward the semiconductor wafer 30 through the gas injection openings 18. The processing gas supplied from the processing gas supply system 15 is, for example, a gaseous mixture of N₂ and O₂, a gaseous mixture of N₂ and H₂ or the like.

A gas exhaust port 19 is formed at a lower portion of the processing chamber 1, and a gas exhaust system 20 is connected to the gas exhaust port 19. By operating a vacuum pump of the gas exhaust system 20, the processing chamber 1 can be depressurized to a specific vacuum level. Further, a gate valve 24 for opening and closing a loading/unloading port for the semiconductor wafer 30 is installed at a sidewall of the processing chamber 1.

A ring magnet 21 is concentrically disposed around the periphery of the processing chamber 1 to form a magnetic field in a processing space between the mounting table 2 and the shower head 16. The ring magnet 21 can be rotated by a rotation mechanism (not shown) such as a motor.

The whole operation of the plasma etching apparatus having the above configuration is controlled by a control unit 60. The control unit 60 includes a process controller 61 having a CPU for controlling each component of the plasma etching apparatus, a user interface 62 and a storage unit 63.

The user interface 62 includes, e.g., a keyboard for a process manager to input a command to operate the plasma etching apparatus, a display for showing an operational status of the plasma etching apparatus, and the like.

The storage unit 63 stores therein, e.g., control programs (software) to be used in realizing various processes, which are performed in the plasma processing apparatus under the control of the process controller 61, and/or recipes including processing condition data and the like. When a command is received from, e.g., the user interface 62, the processing controller 61 retrieves a necessary recipe from the storage unit 63 as required to execute the command to perform a desired process in the plasma processing apparatus under the control of the process controller 61. The control programs and the recipes including the processing condition data and the like can be retrieved from a computer-readable storage medium (e.g., a hard disk, a CD, a flexible disk, a semiconductor memory or the like) or can be transmitted from another apparatus via, e.g., a dedicated line, if necessary.

Hereinafter, a sequence for plasma etching the semiconductor wafer 30, which is performed by the plasma etching apparatus configured as described above, will be explained. First, the gate valve 24 is opened, and the semiconductor wafer 30 is loaded into the processing chamber 1 by, e.g., a transfer robot (not shown) via a load lock chamber (not shown) to be finally mounted on the mounting table 2. Thereafter, the transfer robot is retreated from the processing chamber 1, and the gate valve 24 is closed. Then, the processing chamber 1 is evacuated via the gas exhaust port 19 by the vacuum pump of the gas exhaust system 20.

After the internal pressure of the processing chamber 1 reaches a specific vacuum level, a processing gas (etching gas) is supplied from the processing gas supply system 15 into the processing chamber 1. Then, while maintaining the internal pressure of the processing chamber 1 at a specific pressure level, e.g., about 8.0 Pa, a high frequency power of a frequency of, e.g., 13.56 MHz and a power of, e.g., about 100 to 5000 W is supplied from the RF power supply 10 to the mounting table 2. At this time, a DC voltage is applied from the DC power supply 12 to the electrode 6a of the electrostatic chuck 6, whereby the semiconductor wafer 30 is attracted and held by the electrostatic chuck 6 with the help of a Coulomb force generated by the DC voltage.

In such case, as a result of applying the high frequency power to the mounting table 2, an electric field is formed between the shower head 16 serving as the upper electrode and the mounting table 2 serving as the lower electrode. Meanwhile, since a horizontal magnetic filed is formed in an upper portion la of the processing chamber 1 due to the presence of the ring magnet 21, a magnetron discharge occurs by electron drift in the processing space where the semiconductor wafer 30 is located. As a result, the semiconductor wafer 30 is etched by the plasma of the processing gas generated by the magnetron discharge.

Then, upon the completion of the etching process, the supply of the high frequency power and the processing gas is stopped, and the semiconductor wafer 30 is unloaded from the processing chamber 1 in a reverse sequence to that described above.

Now, the configuration of the focus ring 5 will be explained in connection with FIG. 2. FIG. 2 shows a schematic cross sectional view of major parts of the mounting table 2 on which the focus ring 5 is disposed. In FIG. 2, though gaps are shown to be present between component members of the focus ring 5, the component members are actually in contact with each other (except the one between the semiconductor wafer 30 and the focus ring 5). As shown in the figure, the focus ring 5 includes the first ring-shaped member 5a and the second ring-shaped member 5b disposed thereunder.

The first ring-shaped member 5a is made of a conductive material such as silicon, carbon, SiC or the like. The first ring-shaped member 5a is provided with a stepped portion 50 at an inner edge peripheral thereof, wherein the stepped portion 50 is positioned lower than the bottom surface of the semiconductor wafer 30 mounted on the mounting table 2. The stepped portion 50 is extended below the periphery of the semiconductor wafer 30. Further, the part of the first ring-shaped member 5a outside the stepped portion 50 is formed as a flat portion 51 whose top surface is flat. The flat portion 51 is positioned higher than the stepped portion 50. In other words, the first ring-shaped member 5a is formed of a lower part having an inner diameter smaller than a diameter of the semiconductor wafer 30 and an upper part having an inner diameter greater than the diameter of the semiconductor wafer 30. When installed, the lower part is positioned directly below the periphery of the semiconductor wafer 30 mounted on the mounting table 2. In an initial state before the first ring-shaped member 5a is begun to be used, the top surface of the flat portion 51 is positioned higher than the top surface of the semiconductor wafer 30 held on the mounting table 2. The flat portion 51 of the first ring-shaped member 5a is gradually consumed by being exposed to the plasma, and its height becomes lower gradually. In this embodiment, the thickness (d in FIG. 2) of the first ring-shaped member 5a is set to be several millimeter, e.g., about 4 mm; the thickness (c in FIG. 2) of the stepped portion 50 is set to be, e.g., about 2.5 mm; and the diametric length (e in FIG. 2) of the stepped portion 50 is set to be, e.g., about 2 mm.

The second ring-shaped member 5b is made of, e.g., an insulating material such as alumina, quartz or the like. The second ring-shaped member 5b is disposed under the first ring-shaped member 5a in a manner that it is interposed between the first ring-shaped member 5a and the mounting table 2. That is, the second ring-shaped member 5b is configured so as not to allow the first ring-shaped member 5a to be directly mounted on the mounting table 2. In the present embodiment, the diametric length b of the second ring-shaped member 5b is set to be identical with the diametric length of the first ring-shaped member 5a, as shown in FIG. 2. Further, the thickness of the second ring-shaped member 5b is set to be several millimeters, e.g., about 3 mm. In FIG. 2, the reference numeral 40 is an enclosure made of, e.g., quartz or the like and the reference numeral 41 is an insulator ring made of, e.g., quartz or the like.

The reason why the focus ring 5 has the above configuration is as follows. In the plasma etching apparatus of the type which generates a plasma between the mounting table (lower electrode) 2 and the electrically grounded shower head (upper electrode) 16 by means of applying the high frequency power to the mounting table 2, the intensity (density) of a plasma generated in a space above the focus ring 5 can be reduced by means of using the focus ring 5 having the above configuration in comparison with a conventional case. Accordingly, it is possible to concentrate the plasma in a space above the semiconductor wafer 30 on the mounting table 2. Thus, a plasma intensity (density) in the space above the semiconductor wafer 30 can be increased higher than in the conventional case, whereby a relative difference in plasma intensity (density) is created between the space above the semiconductor wafer 30 and the space above the focus ring 5. As a result, the overall etching rate of the semiconductor wafer 30 can be raised, and an increase or decrease of an etching rate at the edge portion of the semiconductor wafer 30 can be prevented. Thus it becomes possible to improve the in-surface uniformity of the plasma etching process. In order to provide a gradual plasma variation at the boundary region between the plasma formed in the space above the semiconductor wafer and the plasma formed in the space above the focus ring 5, both the first ring-shaped member 5a and the second ring-shaped member 5b are extended below the periphery of the semiconductor wafer 30, as shown in FIG. 2.

In a test example 1, plasma etching of an organic resist mask was performed by using the focus ring 5 having the above-described configuration under the following conditions:

etching gas: N₂/O₂=200/22 sccm;

pressure: 2.26 Pa (17 mTorr);

high frequency power: 300 W;

gap (between the upper electrode and the lower electrode): 40 mm;

temperature of the mounting table: 60° C.;

backside He pressure (edge/center): 931/3325 Pa ( 7/25 Torr).

As a result of the test example 1, an average etching rate was 153.1 nm/min and an in-surface variation of the etching rate was ±2.3% in case of using the second ring-shaped member 5b made of quartz. When the second ring-shaped member 5b made of alumina (Al₂O₃) was used, the average etching rate was 147.4 nm/min and the in-surface variation of the etching rate was ±1.8%.

As a comparative example 1, plasma etching was performed by using a conventional focus ring 500 made up of a single body without having the second ring-shaped member 5b as shown in FIG. 4, wherein the etching conditions for the comparative example were identical with those for the test example 1. As a result, an average etching rate was 144.0 nm/min and the in-surface variation of the in-surface etching rate was ±4.5%. Further, in the comparative example 1, the etching rate was found to be non-uniformly distributed as it increased at the edge portion of the semiconductor wafer 30, whereas this tendency was weakened in the test example 1. Furthermore, the improvement of the in-surface uniformity of the etching rate was more obvious when using the second ring-shaped member 5b made of the alumina than when using the second ring-shaped member 5b made of the quartz. However, the average etching rate was higher when the quartz-made second ring-shaped member 5b was used. As such, when the materials for the second ring-shaped member 5b are different, an impedance against the high frequency power varies due to a difference in such characteristics as a dielectric constant, a dielectric loss and the like, resulting in different results and effects. Thus, a proper insulating material needs to be selected.

As a test example 2, plasma etching of an organic resist mask was performed by using the focus ring 5 having the above-configuration under the following conditions:

etching gas: N₂/H₂=200/600 sccm;

pressure: 7.98 Pa (60 mTorr);

high frequency power: 700 W;

gap (between the upper electrode and the lower electrode): 40 mm;

temperature of the mounting table : 20° C.;

backside He pressure (edge/center) : 931/3325 Pa ( 7/25 Torr).

As a result of the test example 2, when the ring-shaped member 5b was made of quartz, an average etching rate was 150.7 nm/min and an in-surface variation of the etching rate was ±4.8%. Further, when the ring-shaped member 5b was made of alumina (Al₂O₃), the average etching rate was 145.5 nm/min and the in-surface variation of the etching rate was ±3.2%.

As a comparative example 2, plasma etching was performed by using the conventional focus ring 500 made up of the single body without having the second ring-shaped member 5b, as shown in FIG. 4, wherein the etching conditions therefor were identical with those for the test example 2. As a result, an average etching rate was 134.7 nm/min and an in-surface variation of the etching rate was ±5.5%. Further, in the comparative example 2, the etching rate was found to be non-uniformly distributed as it decreased at the edge portion of the semiconductor wafer 30, whereas this tendency was weakened in the test example 2. Furthermore, the improvement of the in-surface uniformity of the etching rate was more obvious when using the second ring-shaped member 5b made of the alumina than when using the second ring-shaped member made of the quartz. However, the average etching rate was higher when the quartz-made second ring-shaped member 5b was used. The results of the aforementioned examples are provided in Table 1 below.

TABLE 1

| | | Etching rate | Variation |
|---|---|---|---|
| | | (nm/min) | (%) |
| Test example 1 | Quartz | 153.1 | 2.3 |
| | Alumina | 147.4 | 1.8 |
| Comparative example 1 | | 144 | 4.5 |
| Test example 2 | Quartz | 150.7 | 4.8 |
| | Alumina | 145.7 | 3.2 |
| Comparative example 2 | | 134.7 | 5.5 |

As can be seen from the results of the test examples 1 and 2, it was possible in accordance with the present embodiment to concentrate the plasma in the space above the semiconductor wafer 30 by reducing the plasma intensity (density) in the space above the focus ring 5. Thus, the plasma intensity (density) in the space above the semiconductor wafer 30 could be higher than in the conventional case, resulting in an increase of the etching rate thereat. Further, by reducing the influence of the plasma formed in the space above the focus ring 5, the non-uniformity problem of the etching rate at the edge portion of the semiconductor wafer 30 could be ameliorated, whereby the wafer in-surface uniformity of the etching rate could be improved. Such improvement was evident in both cases where the etching rate decreases at the edge portion of the semiconductor wafer 30 and where the etching rate increases thereat.

Moreover, since deposition is generated when the processing gas of N₂/H₂ is used as in the test example 2, the etching rate at the edge portion of the semiconductor wafer 30 can be controlled to increase by reducing the plasma intensity in the space above the focus ring 5. Meanwhile, in case a gas system which does not incur deposition is used as in the test example 1, the etching rate of the edge portion of the semiconductor wafer 30 can be controlled to decrease by reducing the plasma intensity in the space above the focus ring 5.

To investigate the effect of the intensity (density) reduction of the plasma formed in the space above the focus ring 5, which is expected to be obtained by the focus ring 5 of the present embodiment described above, the surface temperature of the focus ring 5 (whose second ring-shaped member 5b was made of quartz) was measured at five locations on the surface thereof after a lapse of five minutes since the plasma had been generated. As a result, an average temperature was 140° C. Meanwhile, the same measurement was performed on the focus ring 500 used in the comparative examples, and its average temperature was 176° C. From this result, it is confirmed that the focus ring 5 has an effect of reducing the intensity (density) of the plasma formed in the space thereabove.

Further, as shown in FIGS. 4A and 4B, the surface of the focus ring 500 is gradually etched and consumed awhile being used, and, thus, its height becomes lower gradually (see FIG. 4B). Accordingly, the state of the plasma formed on the semiconductor wafer 30 varies depending on the consumption of the focus ring 500. As an example, etching was conducted to form a line-shaped SiO₂ layer by using the focus ring 500, while using a KrF resist as a mask. In an initial state shown in FIG. 4A, the line width was 130 nm, whereas the line width increased to 131.9 nm in the state of FIG. 4B where the focus ring 500 has been used for 210 hours. That is, a CD shift of about 2 nm was generated. The generation of such CD shift is deemed to be due to the variation of the plasma formed on the semiconductor wafer 30. Such variation seems to be due to the fact that the plasma originally formed above the focus ring 500 in the initial state gradually spreads into the space above the semiconductor wafer 30 with the consumption of the focus ring 500.

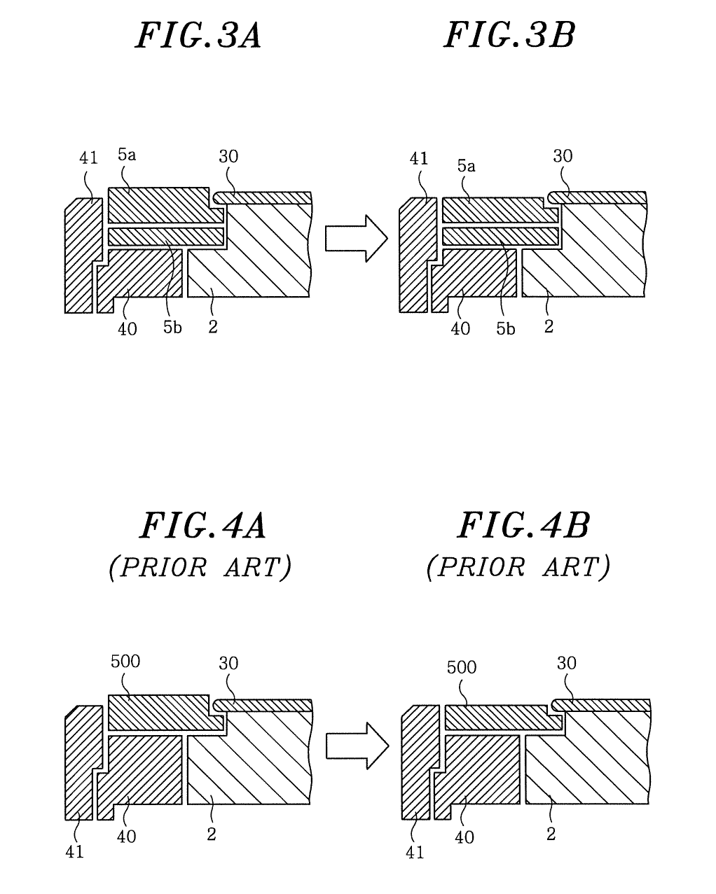

Meanwhile, the same plasma etching was performed by using the focus ring 5 of the present embodiment. In the initial state shown in FIG. 3A, the line width was 130.2 nm and after the focus ring 5 has been used for 210 hours, the line width became 129.8 nm as in the state of FIG. 3B. That is, the CD shift could be reduced to 0.4 nm. Such reduced CD shift is thought to be due to the fact that even though the intensity of the plasma formed above the focus ring 5 varies due to the consumption of the focus ring 5, the influence of this variation on the plasma above the semiconductor wafer 30 is small, because the plasma intensity above the focus ring 5 was low in the initial state by using the focus ring 5. As described, the focus ring 5 in accordance with the present embodiment also has an effect of reducing the CD shift due to the consumption of the focus ring 5.

Here, it is to be noted that the present invention is not limited to the embodiment described above but it can be modified in various ways. For example, the plasma etching apparatus is not limited to the parallel plate type etching apparatus of the type that applies a single high frequency power to the lower electrode as exemplified above, but the present invention can be applied to a plasma etching apparatus of a type that applies dual frequency powers to the lower electrode.

While the invention has been shown and described with respect to the embodiment, it will be understood by those skilled in the art that various changes and modifications may be made without departing from the scope of the invention as defined in the following claims.

What is claimed is:

1. A focus ring of a plasma processing apparatus for performing a plasma processing on a target substrate to be processed by applying a high frequency power to a mounting table mounting thereon the target substrate and generating a plasma in a space between the mounting table and an electrically grounded upper electrode disposed to face the mounting table, the focus ring being disposed on the mounting table to surround the target substrate and comprising:
a first ring-shaped member made of a conductive material and having a stepped portion at an inner peripheral portion thereof, the stepped portion being positioned lower than a bottom surface of the target substrate mounted on the mounting table and extended below a peripheral portion of the target substrate; and
a second ring-shaped member made of an insulating material and disposed under the first ring-shaped member to be interposed between the first ring-shaped member and the mounting table.

2. The focus ring of claim 1, wherein the second ring-shaped member is made of alumina.

3. The focus ring of claim 1, wherein the first ring-shaped member is made of silicon, carbon or SiC.

4. The focus ring of claim 2, wherein the first ring-shaped member is made of silicon, carbon or SiC.

5. The focus ring of claim 1, wherein a top surface of a portion of the first ring-shaped member outside the stepped portion is formed as a flat portion positioned higher than a top surface of the target substrate mounted on the mounting table.

6. The focus ring of claim 2, wherein a top surface of a portion of the first ring-shaped member outside the stepped portion is formed as a flat portion positioned higher than a top surface of the target substrate mounted on the mounting table.

7. The focus ring of claim 3, wherein a top surface of a portion of the first ring-shaped member outside the stepped portion is formed as a flat portion positioned higher than a top surface of the target substrate mounted on the mounting table.

8. The focus ring of claim 4, wherein a top surface of a portion of the first ring-shaped member outside the stepped portion is formed as a flat portion positioned higher than a top surface of the target substrate mounted on the mounting table.

9. A plasma processing apparatus comprising:
a processing chamber for performing a plasma process on a target substrate to be processed accommodated therein;
a mounting table, disposed in the processing chamber, for mounting thereon the target substrate;
a high frequency power supply for generating a plasma by supplying a high frequency power to the mounting table;
an electrically grounded upper electrode disposed to face the mounting table and electrically grounded;
a focus ring disposed on the mounting table to surround the target substrate, the focus ring including a first ring-shaped member made of a conductive material and having a stepped portion at an inner peripheral portion thereof, is the stepped portion being positioned lower than a bottom surface of the target substrate mounted on the mounting table and extended below a peripheral portion of the target substrate; and a second ring-shaped member made of an insulating material and disposed under the first ring-shaped member to be interposed between the first ring-shaped member and the mounting table.

10. The plasma processing apparatus of claim 9, wherein the second ring-shaped member is made of alumina.

11. The plasma processing apparatus of claim 9, wherein the first ring-shaped member is made of silicon, carbon or SiC.

12. The plasma processing apparatus of claim 10, wherein the first ring-shaped member is made of silicon, carbon or SiC.

13. The plasma processing apparatus of claim 9, wherein a top surface of a portion of the first ring-shaped member outside the stepped portion is formed as a flat portion positioned higher than a top surface of the target substrate mounted on the mounting table.

14. The plasma processing apparatus of claim 10, wherein a top surface of a portion of the first ring-shaped member outside the stepped portion is formed as a flat portion positioned higher than a top surface of the target substrate mounted on the mounting table.

15. The plasma processing apparatus of claim 11, wherein a top surface of a portion of the first ring-shaped member outside the stepped portion is formed as a flat portion positioned higher than a top surface of the target substrate mounted on the mounting table.

16. The plasma processing apparatus of claim 12, wherein a top surface of a portion of the first ring-shaped member outside the stepped portion is formed as a flat portion positioned higher than a top surface of the target substrate mounted on the mounting table.
